(19) United States
(12) Patent Application Publication
(10) Pub. No.: US 2012/0299615 A1
(43) Pub. Date: Nov. 29, 2012

(54) CIRCUIT BOARD ASSEMBLY AND ASSISTANT TEST CIRCUIT BOARD

(75) Inventor: FA-SHENG HUANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/192,782

(22) Filed: Jul. 28, 2011

(30) Foreign Application Priority Data
May 27, 2011 (CN) 201110139898.7

(51) Int. Cl. G01R 31/28

(52) U.S. Cl. 324/763.01

(57) ABSTRACT

An assistant test circuit board for assisting a tester to test a number of signal welds and a number of ground welds on a printed circuit board includes a ground pin, a same number of ground pads as ground welds, test pads, and a same number of test pins as signal welds. Each test pad and each ground pad located on a fist side of the circuit board are soldered to the corresponding signal weld and ground weld, while the test pins and the ground pin are connected to the tester.

### BACKGROUND

1. Technical Field

The present disclosure relates to a circuit board assembly having an assistant test circuit board.

2. Description of Related Art

With the technology of integrated circuit developing, there are more and more components, such as chips, mounted on a printed circuit board. When the circuitry of the printed circuit board needs to be tested, the test pins of the tester are generally soldered to the printed circuit board, which may result in short circuit due to the high density of the components on the printed circuit board. Furthermore, soldering the test pins for every test is time-consuming.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic diagram of an exemplary embodiment of a first side of an assistant test circuit board.

FIG. 2 is a schematic diagram of a second side of the assistant test circuit board of FIG. 1.

FIG. 3 is a schematic diagram of an exemplary embodiment of a printed circuit board connected to the assistant test circuit board.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

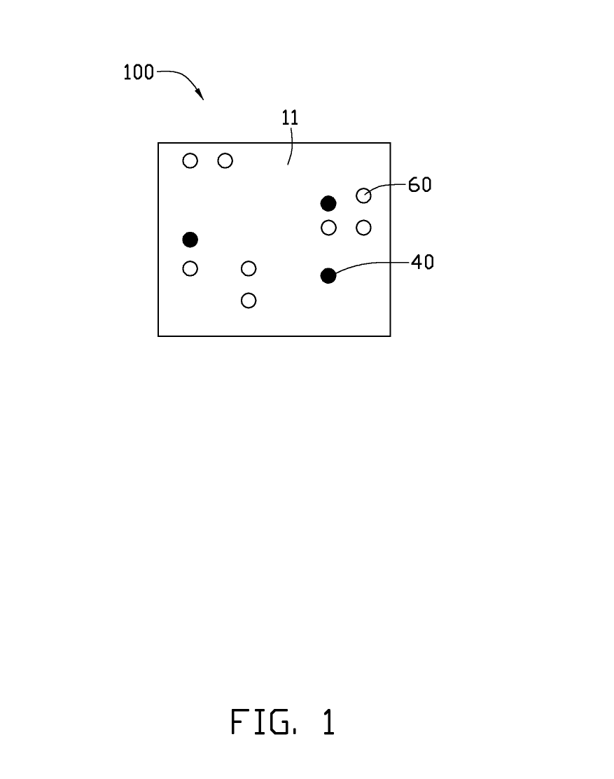

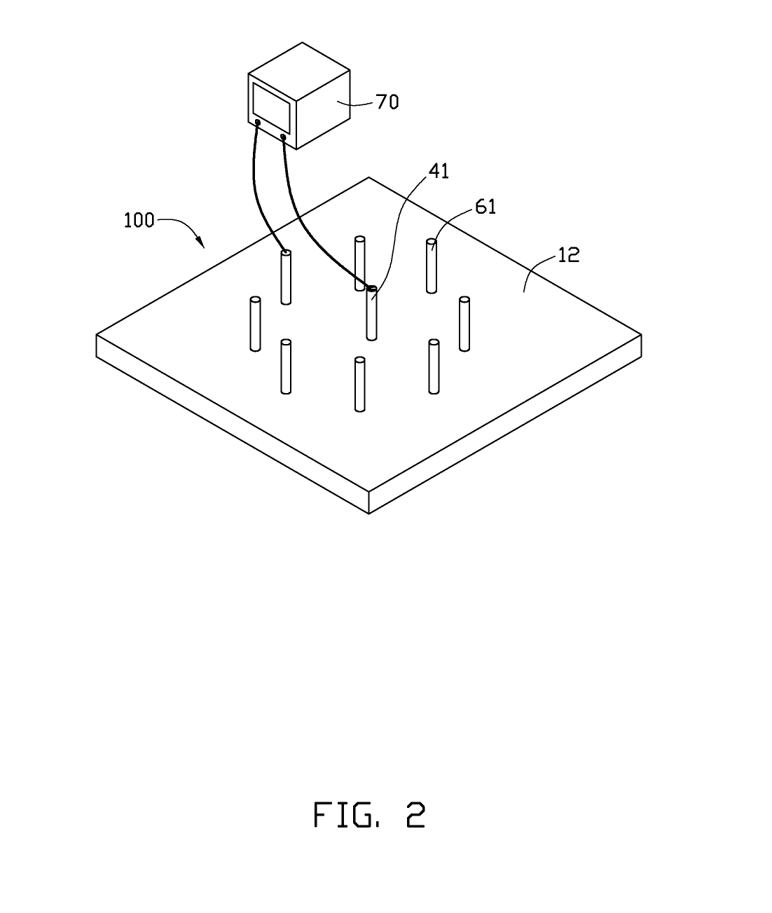

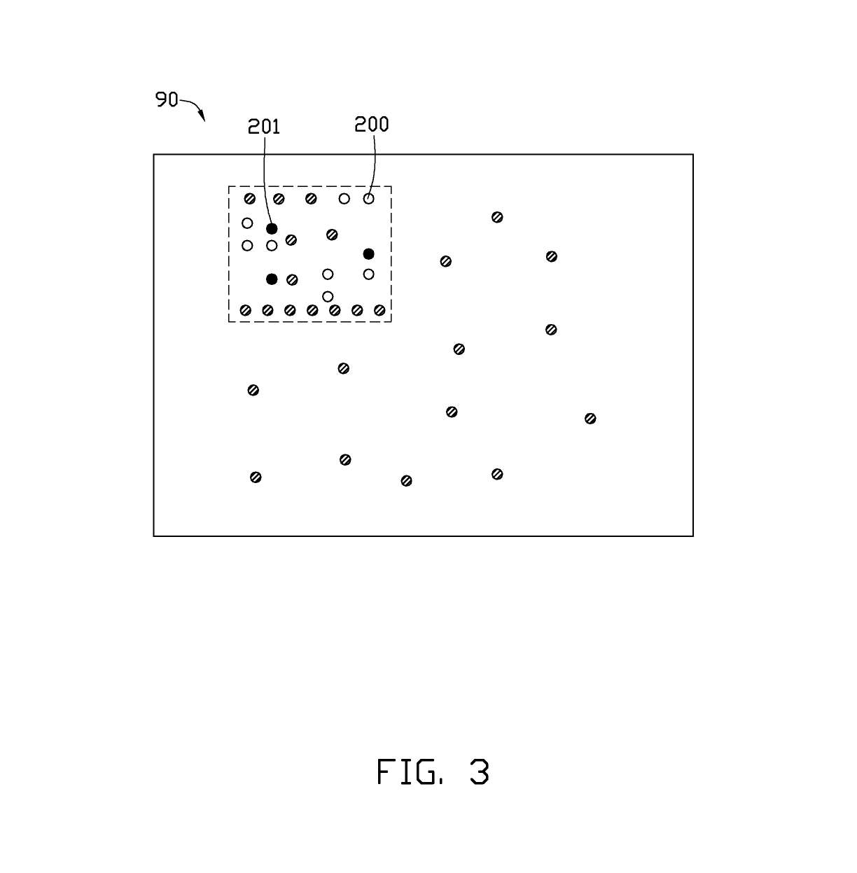

Referring to FIGS. 1-3, an assistant test circuit board 100 is configured for assisting a tester 70 to test a plurality of signal welds 200 and a plurality of ground welds 201 on a printed circuit board 90. An exemplary embodiment of the assistant test circuit board 100 includes at least one ground pad 40 for each of the ground welds 201, and at least one test pad 60 and one test pin 61 for each of the signal welds 200.

The signal welds 200 and the ground welds 201 are on a bottom side of the printed circuit board 90, opposite to a top side of the printed circuit board 90 where electronic components, such as chips, are arranged.

The test pads 60 and the ground pads 40 are arranged on a first side 11 of the assistant test circuit board 100, corresponding to the arrangement of the signal welds 200 and the ground welds 201 on the printed circuit board 90. That is to say, each test pad 60 corresponds to a corresponding one of the signal welds 200, and each ground pad 40 corresponds to a corresponding one of the ground welds 201. Therefore, the test pads 60 and the ground pads 40 can be soldered to the corresponding signal welds 200 and ground welds 201. The ground pads 40 are electrically connected to one another.

The test pins 61 and the ground pin 41 are mounted on a second side 12 of the assistant test circuit board 100 opposite to the first side 11. Each test pin 61 is electrically coupled to a corresponding test pad 60, and the ground pin 41 is electrically connected to any ground pad 40. In this embodiment, the test pins 61 are arranged in a circle whose center corresponds to the location of the ground pin 41. In other embodiments, the test pins 61 may be arranged in another shape, such as a triangle, square, or line, according to need.

In use, each test pad 60 is soldered to a corresponding signal weld 200, and each ground pad 40 is soldered to a corresponding ground weld 201. Therefore, the circuit board 100 is fixed to the bottom side of the printed circuit board 90, thereby avoiding welding among the densely packed components of the printed circuit board 90. Each test pad 60 and each ground pad 40 are electrically connected to the corresponding testing weld 200 and the corresponding ground weld 201. The tester 70 is connected to the ground pin 41 and one of the test pins 61 to receive signals from the corresponding signal weld 200, thereby testing the signal weld 200.

The foregoing description of the exemplary embodiments of the disclosure has been presented only for the purposes of illustration and description and is not intended to be exhaustive or to limit the disclosure to the precise forms disclosed. Many modifications and variations are possible. The embodiments were chosen and described in order to explain the principles of the disclosure and their practical application so as to enable others of ordinary skill in the art to utilize the disclosure and various embodiments and with such various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than by the foregoing description and the exemplary embodiments described therein.

What is claimed is:

1. An assistant test circuit board for assisting a tester to test a plurality of signal welds and a plurality of ground welds on a printed circuit board, the assistant test circuit board comprising:
at least one ground pad for each of the ground welds, wherein the ground pads are connected to one another, and mounted on a first side of the assistant test circuit board, to be soldered to the ground welds;
at least one test pad for each of the signal welds, wherein the test pads are mounted on the first side of the assistant test circuit board, to be soldered to the corresponding signal welds;
a ground pin extending from a second side of the assistant test circuit board opposite to the first side, and electrically connected to the ground pads, to be electrically connected to the tester; and
at least one test pin for each of the signal welds, wherein the test pins extend from the second side of the assistant test circuit board opposite to the first side, to be electrically connected to the tester.

2. A circuit board assembly, comprising:
a printed circuit board, comprising a plurality of signal welds and a plurality of ground welds arranged on a side of the printed circuit board; and
an assistant test circuit board mounted to the side of the printed circuit board, the assistant test circuit board comprising:
at least one ground pad for each of the ground welds, wherein the ground pads are electrically connected to one another, and mounted on a first side of the assistant test circuit board facing the side of the printed circuit board, the ground pads are soldered to the ground welds;
at least one test pad for each of the signal welds, wherein the test pads are mounted on the first side of the assistant test circuit board, and soldered to the corresponding signal welds;
a ground pin arranged on a second side of the assistant test circuit board and electrically connected to the ground pads; and
at least one test pin for each of the signal welds, wherein the test pins are arranged on the second side of the assistant test circuit board.

3. The circuit board assembly of claim 2, wherein the signal welds and the ground welds are located on the bottom side of the printed circuit board.
